(19) United States
(12) Patent Application Publication
(10) Pub. No.: US 2026/0156750 A1
(43) Pub. Date: Jun. 4, 2026

(54) PRINTED CIRCUIT BOARD

(71) Applicant: SAMSUNG ELECTRO-MECHANICS CO., LTD., Suwon-si (KR)

(72) Inventors: Dae Hui JO, Suwon-si (KR); Ji Hwan SEOL, Suwon-si (KR)

(73) Assignee: SAMSUNG ELECTRO-MECHANICS CO., LTD., Suwon-si (KR)

(21) Appl. No.: 19/261,021

(22) Filed: Jul. 7, 2025

(30) Foreign Application Priority Data
Dec. 4, 2024 (KR) 10-2024-0178478

(51) Int. Cl. H05K 1/14; H05K 1/09; H05K 1/11

(52) U.S. Cl. CPC H05K 1/142; H05K 1/09; H05K 1/111; H05K 1/115; H05K 1/144; H05K 2201/0338; H05K 2201/0352; H05K 2201/042; H05K 2201/09563; H05K 2201/096

(57) ABSTRACT

A printed circuit board includes a first substrate portion including a pad including a first metal, the pad being disposed in an upper portion of the first substrate portion; a second substrate portion disposed on the first substrate portion; a bridge at least partially disposed within the second substrate portion, and including a bridge pad including a second metal, disposed in a lower portion of the bridge; and a conductive connection portion disposed between the pad and the bridge pad. The conductive connection portion includes a first conductive layer including a third metal, a second conductive layer disposed below the first conductive layer and including the first metal and the third metal, and a third conductive layer disposed above the first metal layer and including the second metal and the third metal.

### CROSS-REFERENCE TO RELATED APPLICATION(S)

This application claims benefit of priority to Korean Patent Application No. 10-2024-0178478 filed on Dec. 4, 2024 in the Korean Intellectual Property Office, the disclosure of which is incorporated herein by reference in its entirety.

### TECHNICAL FIELD

The present disclosure relates to a printed circuit board.

Recently, due to the development of artificial intelligence (AI) technology, etc., multi-chip packages that include memory chips such as High Bandwidth Memory (HBM) for exponentially increased data processing and processor chips such as Central Processing Unit (CPU), Graphics Processing Unit (GPU), Application Specific Integrated Circuit (ASIC), and Field Programmable Gate Array (FPGA) are being used.

Meanwhile, a technology is being developed to electrically connect semiconductor chips mounted on the substrate by embedding bridges containing microcircuits in the printed circuit board used in the multi-chip package.

Bridge-embedding substrates of the related art are manufactured by manufacturing cavities and then performing Die Attach Film (DAF) and embedding, or by manufacturing a separate substrate, attaching it to it, and filling the remaining portion with insulating material.

In this case, the aspect ratio of the cavity becomes large, making it difficult to secure fairness, and there is also the disadvantage of having to use expensive Die Attach Film (DAF).

### SUMMARY

An aspect of the present disclosure is to provide a printed circuit board having a bridge embedded therein, including a high-density circuit layer and a method for manufacturing the same.

According to an aspect of the present disclosure, a printed circuit board includes a first substrate portion including a pad including a first metal, the pad being disposed in a first portion of the first substrate portion; a second substrate portion disposed on the first substrate portion; a bridge at least partially disposed within the second substrate portion, and including a bridge pad including a second metal, the bridge pad being disposed in a first portion of the bridge; and a conductive connection portion disposed between the pad and the bridge pad. The conductive connection portion includes a first conductive layer including a third metal, a second conductive layer including the first metal and the third metal, and a third conductive layer including the second metal and the third metal. The first conductive layer is disposed between the second conductive layer and the third conductive layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system.

FIG. 2 is a perspective view schematically illustrating an example of an electronic device.

FIG. 3 is a cross-sectional view schematically illustrating a first embodiment of a printed circuit board according to the present disclosure.

FIG. 4 is an enlarged view of portion A of FIG. 3.

FIGS. 5 to 9 are drawings schematically illustrating a manufacturing process of a first embodiment of a printed circuit board according to the present disclosure.

FIG. 10 is a cross-sectional view schematically illustrating a second embodiment of a printed circuit board according to the present disclosure.

FIG. 11 is an enlarged view of part B of FIG. 10.

FIGS. 12 to 16 are drawings schematically illustrating a manufacturing process of a second embodiment of a printed circuit board according to the present disclosure.

FIG. 17 is a drawing schematically illustrating a modified example of the second embodiment of a printed circuit board according to the present disclosure.

FIG. 18 is a cross-sectional view schematically illustrating a third embodiment of a printed circuit board according to the present disclosure.

FIGS. 19 to 24 are drawings schematically illustrating a manufacturing process of a third embodiment of a printed circuit board according to the present disclosure.

### DETAILED DESCRIPTION

Hereinafter, the present disclosure will be described with reference to the attached drawings. The shapes and sizes of elements in the drawings may be exaggerated or reduced for a clearer explanation.

### Electronic Devices

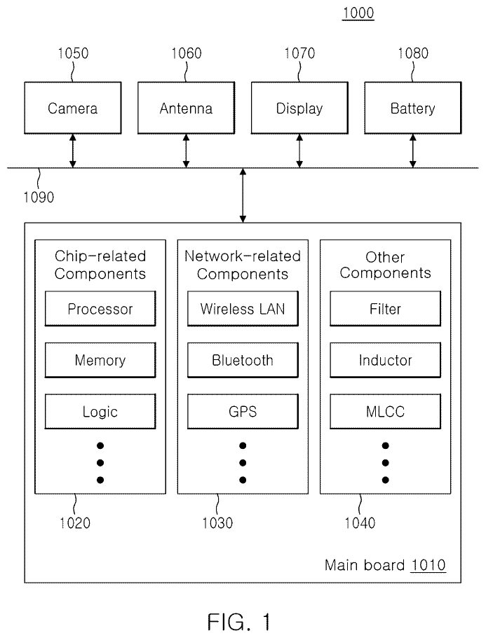

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to other electronic components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related electronic components. In addition, the chip related components 1020 may also be combined with each other. The chip-related component 1020 may be in the form of a package including the aforementioned chip or electronic component.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access +(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive elements in the form of chip components used for various other purposes, and the like. In addition, other components 1040 may also be combined with the chip related components 1020 and/or the network related components 1030.

Depending on a type of the electronic device 1000, the electronic device 1000 may include other electronic components that may or may not be physically or electrically connected to the mainboard 1010. These other electronic components may include, for example, a camera module 1050, an antenna module 1060, a display device 1070, a battery 1080, and the like, but are not limited thereto. These other electronic components may be an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. In addition, these other electronic components may also include other electronic components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, a server, or the like. However, the electronic device 1000 is not limited thereto, but may be any other electronic device processing data.

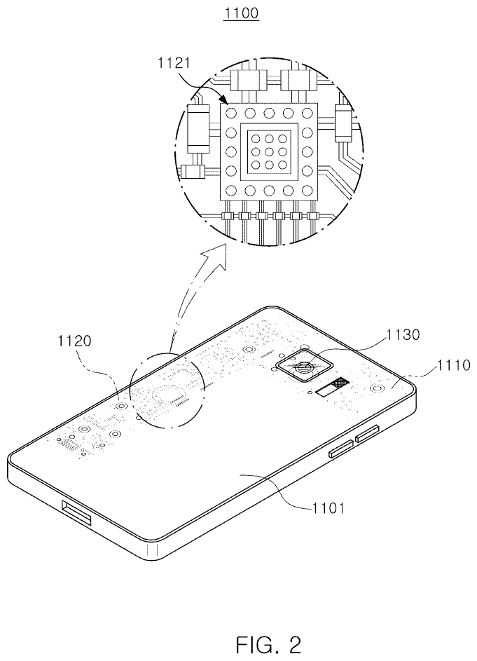

FIG. 2 is a perspective view schematically illustrating an example of an electronic device.

Referring to the drawing, the electronic device may be, for example, a smartphone (1100). A main board (1110) is accommodated inside the smartphone (1100), and various electronic components (1120) are physically and/or electrically connected to this main board (1110). In addition, other electronic components, such as a camera module (1130) and/or a speaker (1140), which may or may not be physically and/or electrically connected to the main board (1110), are accommodated inside. Some of the electronic components (1120) may be the chip-related components described above, and may be, for example, a semiconductor package (1121), but are not limited thereto. The semiconductor package (1121) may be a surface-mounted form, such as a semiconductor chip or a passive component, on a package substrate in the form of a multilayer electronic component embedded substrate, but are not limited thereto. Meanwhile, the electronic device is not necessarily limited to a smartphone (1100), and may of course be another electronic device as described above.

### First Embodiment

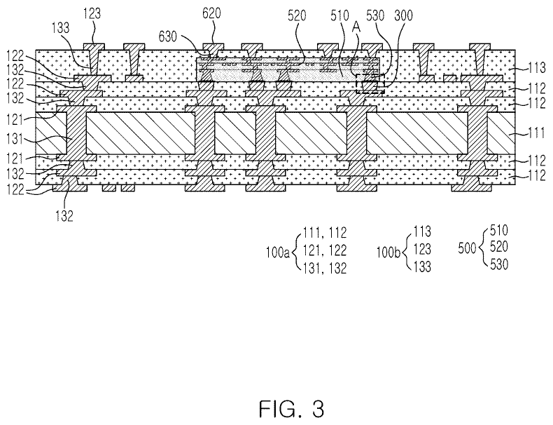

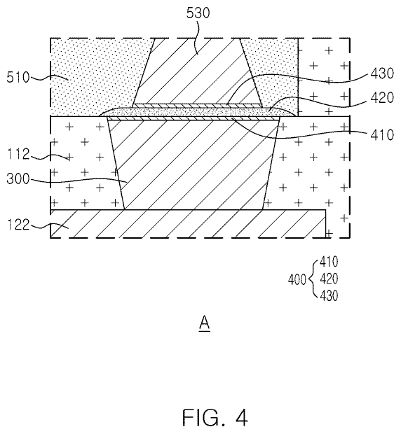

FIG. 3 is a cross-sectional view schematically illustrating a first embodiment of a printed circuit board according to the present disclosure. FIG. 4 is an enlarged view of portion A of FIG. 3.

Referring to the drawing, the printed circuit board according to the first embodiment may include a first substrate portion (100a) in which a pad (300) is disposed on the upper portion (e.g., first portion of the first substrate portion), a second substrate portion (100b) disposed on the first substrate portion, a bridge (500) in which at least a portion is disposed within the second substrate portion and a bridge pad (530) is disposed on the lower portion (e.g., a first portion of the bridge), and a conductive connection portion (400) disposed between the pad and the bridge pad.

The first substrate portion (100a) may include a core layer (111), a core interconnection layer (121), a through-via (131), a first insulating layer (112), a first interconnection layer (122), and a first via layer (132).

The first substrate portion (100a) has a pad (300) disposed thereon, which includes a first metal. The pad (300) may be exposed from an upper surface of the uppermost first insulating layer (112), and may be connected to a bridge pad (530) of a bridge (500) through a conductive connection portion (400).

The pad (300) may include a first metal. The first metal may be copper (Cu), aluminum (Al), silver (Ag), tin (Sn), gold (Au), nickel (Ni), lead (Pb), titanium (Ti), and/or alloys thereof, and may preferably be copper (Cu), but is not limited thereto.

The pad (300) may be formed by one of the SAP (Semi Additive Process), MSAP (Modified Semi Additive Process), TT (Tenting), or subtractive methods, but is not limited thereto. The pad (300) may include an electroless plating layer (or chemical copper) as a seed layer and an electrolytic plating layer (or electrolytic copper) as a plating layer, but is not limited thereto. A sputtering layer may be formed instead of chemical copper as the electroless plating layer. If necessary, a copper foil may be further included.

The first insulating layer (112) may be formed by one or more layers, and may be a build-up insulating layer formed on the core layer (111) as described below. Hereinafter, the first insulating layer (112) may refer to the uppermost insulating layer among a plurality of first insulating layers (112) based on FIG. 3 for convenience. However, it is not limited thereto.

The first insulating layer (112) may include an insulating material. The insulating material may include a thermosetting resin such as an epoxy resin, a thermoplastic resin such as a polyimide, or a material including an inorganic filler, an organic filler, and/or glass fiber (Glass Fiber, Glass Cloth, and/or Glass Fabric) together with such a resin. The insulating material may be a photosensitive material and/or a non-photosensitive material. For example, as the insulating material, an insulating material such as SR (Solder Resist), ABF (Ajinomoto Build-up Film), FR-4, BT (Bismaleimide Triazine), PPG (Prepreg), RCC (Resin Coated Copper), CCL (Copper Clad Laminate) may be used, but is not limited thereto, and other polymer materials may be used in addition.

The first insulating layer (112) may include one side and the other side facing the one side. One side of the first insulating layer (112) may be a side on which the bridge (500) is mounted, and the upper surface may refer to the upper surface of the first insulating layer (112) based on FIG. 3.

The first interconnection layer (122) may be disposed on or within the first insulating layer (112). The first interconnection layer (122) may be a build-up interconnection layer disposed on or within the upper surface of the first insulating layer (112). The first interconnection layer (122) may be connected to at least one of the first interconnection layer (122) disposed in another layer, the core interconnection layer (121), and the second interconnection layer (123).

The first interconnection layer (122) may include a metal material. As the metal material, copper (Cu), aluminum (Al), silver (Ag), tin (Sn), gold (Au), lead (Pb), titanium (Ti), or alloys thereof may be used. The metal material may preferably include copper (Cu), but is not limited thereto. The first interconnection layer (122) may perform various functions according to the design. For example, it may include a signal pattern, a power pattern, a ground pattern, etc., and is not limited thereto. It may also function as a pad for mounting electronic components and chips, or may function as a stopper for forming a cavity. These patterns may each have various shapes, such as a line, a plane, or a pad. The first interconnection layer (122) may have different pitches depending on its function. When the first interconnection layer (122) requires a high-density fine pitch for connection with a connection structure or a semiconductor chip, the gap between the first interconnection layers (122) may be narrowed, and when performing other signal connections, the gap between the first interconnection layers (122) may be widened.

The first interconnection layer (122) may be formed by any one of the SAP (Semi Additive Process), MSAP (Modified Semi Additive Process), TT (Tenting), or subtractive methods, but is not limited thereto. The first interconnection layer (122) may include an electroless plating layer (or chemical copper) as a seed layer and an electrolytic plating layer (or electrolytic copper) as a plating layer, but is not limited thereto. Instead of chemical copper as the electroless plating layer, a sputtering layer may be formed. If necessary, a copper foil may be further included.

The first via layer (132) may penetrate the first insulating layer (112) to connect the first interconnection layer (122) to the first interconnection layer (122) disposed in another layer and/or the core interconnection layer (121). As a result, an electrical path may be formed in the printed circuit board. The first via layer (132) may perform various functions in the printed circuit board depending on the design of the corresponding layer. For example, it may include a ground via, a power via, a signal via, etc. The first via layer (132) may include a plurality of connection vias, and each connection via may include a conductive material, specifically, a metal material, such as copper (Cu), aluminum (Al), silver (Ag), tin (Sn), gold (Au), nickel (Ni), lead (Pb), titanium (Ti), or alloys thereof. Each of these may include an electroless plating layer (or chemical copper) and an electrolytic plating layer (or electrolytic copper). Each connecting via may be a type filled with a conductive material, but is not limited thereto, and may also be a conformal type in which a conductive material is disposed along the wall surface of the via hole. Each connecting via may have a tapered side surface.

The core layer (111) may be disposed on the other surface (bottom surface) of the lowermost first insulating layer (112). The core layer (111) may have a thickness thicker than each of the first insulating layer (112) and the second insulating layer (113). The material of the core layer (111) is not particularly limited, and any material having insulating properties may be used. For example, a copper clad laminate (CCL) or an unclad copper clad laminate (Unclad CCL) may be used. Alternatively, it may be composed of other types of materials such as a glass substrate or a ceramic substrate, but is not limited thereto. In the drawing, the core layer (111) is depicted as a single layer, but the printed circuit board may have a multilayer core substrate structure in which multiple core layers (111) are laminated depending on the design.

The core interconnection layer (121) may be disposed on both sides of the core layer (111). The core interconnection layer (121) may include a ground pattern, a power pattern, a signal pattern, etc. depending on the design. The core interconnection layer (121) may include a conductive material, and may include, for example, a known metal material that may be used in a circuit layer.

The through-via (131) may penetrate the core layer (111) and connect the core interconnection layer (121) disposed on both sides of the core layer (111). The through-via (131) may include a conductive material. The through-via (131) may be completely filled with a conductive material, or the conductive material may be formed along the wall of the via hole. If the through-via (131) is formed with a conductive material along the wall of the via hole, the interior of the via hole may be filled with an insulating material.

The second substrate portion (100b) is disposed on the first substrate portion (100a). The second substrate portion (100b) may have at least a portion of the bridge (500) disposed therein. The second substrate portion (100b) may contact at least a portion of the side surface of the bridge (500). The second substrate portion (100b) may cover the upper surface (e.g., first surface) of the bridge (500). However, it is not limited thereto, and the second substrate portion (100b) may not cover the upper surface of the bridge (500).

The second substrate portion (100b) may include a second insulating layer (113), a second interconnection layer (123), and a second via layer (133). The second substrate portion (100b) may include a second insulating layer (113) covering at least a portion of the side surface of the bridge, a second interconnection layer (123) disposed on the second insulating layer, and a second via layer (133) penetrating at least a portion of the second insulating layer.

The second insulating layer (113) may be disposed on one surface of the first insulating layer (112). The second insulating layer (113) may cover at least a portion of the side surface of the bridge (500). Since the bridge (500) has at least a portion of its side surface covered by the second insulating layer (113), the printed circuit board according to the present disclosure may be a printed circuit board having a bridge built into it. In the printed circuit board according to the present embodiment, a method of forming a separate cavity, mounting the bridge in the cavity, and then embedding it with an insulating material, etc. may not be used. Therefore, the second insulating layer (113) may be in contact with the side surface of the bridge (500) and at the same time, may be in direct contact with the first insulating layer (112).

Referring to FIG. 3, the second insulating layer (113) is described as covering the upper surface of the bridge (500) so that the bridge (500) is buried by the second insulating layer (113), but is not limited thereto.

The second insulating layer (113) may include an insulating material, and may include the same insulating material as the first insulating layer (112), but is not limited thereto, and may include one of the insulating materials that may be used as the first insulating layer (112).

The second interconnection layer (123) is disposed on the second insulating layer (113) and may be connected to the first interconnection layer (122) through the second via layer (133). The second interconnection layer (123) may include a metal material. The metal material may include copper (Cu), aluminum (Al), silver (Ag), tin (Sn), gold (Au), nickel (Ni), lead (Pb), titanium (Ti), and/or alloys thereof, and may preferably include copper (Cu), but is not limited thereto. The second interconnection layer (123) may be a general circuit pattern and may perform various functions depending on the design, such as mounting components. The second interconnection layer (123) may be formed by any one of a Semi Additive Process (SAP), a Modified Semi Additive Process (MSAP), a Tenting (TT), or a subtractive method, but is not limited thereto. Meanwhile, the second interconnection layer (123) may function as a pad for mounting components. Meanwhile, although not shown in FIG. 3, an electronic component may be mounted on one side of the second interconnection layer (123), and the electronic component may be a known active component or passive component, but is not limited thereto, and another substrate, for example, a printed circuit board including a re-interconnection layer, may be mounted, and may be connected to an interposer that connects between substrates or connects between a substrate and a chip.

The second via layer (133) may connect the second interconnection layer (123) to the first interconnection layer (122). The second via layer (133) may include a metal material. As the metal material, copper (Cu), aluminum (Al), silver (Ag), tin (Sn), gold (Au), nickel (Ni), lead (Pb), titanium (Ti), or alloys thereof may be used. The second via layer (133) may include signal vias, ground vias, power vias, etc., depending on the design. The second via layer (133) may include a plurality of vias, and each via hole may be completely filled with a metal material, or the metal material may be formed along the wall surface of the via hole. The second via layer (133) may be formed by a plating process, for example, a Semi Additive Process (SAP), a Modified Semi Additive Process (MSAP), a Tenting (TT), etc., and may include a seed layer, which is an electroless plating layer, and an electrolytic plating layer formed based on the seed layer.

The bridge (500) is disposed at least partially in the second substrate portion (100b). The bridge (500) may be disposed on one surface of the first insulating layer (112). The bridge (500) may include one surface, a surface facing the one surface, and a side surface. The first insulating layer (112) may be disposed on the one surface of the bridge (500), and the one surface of the bridge (500) may mean the lower surface (e.g., a first surface) of the bridge (500) based on FIG. 3. The lower surface of the bridge (500) may be in direct contact with the uppermost first insulating layer (112). At least a portion of the side surface of the bridge (500) may be in contact with the second insulating layer (113).

The bridge pad (530) may be disposed on the lower surface of the bridge (500) and may function as a means for electrically connecting the bridge (500) and the pad (300). Referring to FIG. 3, the bridge pad (530) may be exposed from the lower surface of the bridge (500).

The bridge pad (530) may include a second metal. The second metal may be copper (Cu), aluminum (Al), silver (Ag), tin (Sn), gold (Au), nickel (Ni), lead (Pb), titanium (Ti), and/or alloys thereof, and may preferably be copper (Cu), but is not limited thereto.

The bridge pad (530) may include the same metal as the pad (300). For example, the first metal may be the same as the second metal. More specifically, the first metal may be copper (Cu).

The bridge pad (530) may be formed by any one of SAP (Semi Additive Process), MSAP (Modified Semi Additive Process), TT (Tenting), or a subtractive method, but is not limited thereto. The pad (300) may include an electroless plating layer (or chemical copper) as a seed layer and an electrolytic plating layer (or electrolytic copper) as a plating layer, but is not limited thereto. A sputtering layer may be formed instead of a chemical copper as an electroless plating layer. If necessary, a copper foil may be further included.

The bridge pad (530) may be disposed to correspond to the pad (300). The fact that the bridge pad (530) is disposed to correspond to the pad (300) may mean that one side of the bridge pad (530) may be disposed to overlap one side of the pad (300) when considering the top view of the printed circuit board.

The bridge (500) may further include a bridge insulating layer (510) and a bridge circuit (520). The bridge circuit (520) may include, in addition to the circuit patterns disposed on the bridge insulating layer (510), vias that penetrate the bridge insulating layer (510) to connect the circuit patterns. In FIG. 3, the bridge insulating layer (510) is depicted as consisting of a total of three layers, but is not limited thereto, and the number of layers of the bridge insulating layer (510) and the bridge circuit (520) may be more or less than that illustrated in the drawing. The bridge (500) may be an organic bridge, and the insulating layer (510) of the bridge (500) may include an organic insulating material. Accordingly, even if disposed on a printed circuit board, reliability problems due to thermal expansion coefficient mismatch may hardly occur. For the formation of microcircuits, a photosensitive insulating material (PID: Photo Image-able Dielectric) may be used as an organic insulating material, but is not limited thereto.

The lower outermost layer of the bridge insulating layer (510) may be in direct contact with the first insulating layer (112). In addition, each bridge insulating layer (510) side surface may be in direct contact with the second insulating layer (113). Since the printed circuit board according to the present disclosure does not mount the bridge in the cavity using a DAF (Die Attach Film) after separate cavity processing, the thin film and pitch precision may be improved. The thickness of each bridge insulating layer (510) may be smaller than the thickness of the first insulating layer (112) or the thickness of another insulating layer. In addition, the density of the bridge circuit (520) may be smaller than the density of the first interconnection layer (121) or the density of another interconnection layer. For example, the bridge (500) may be formed smaller than other insulating layers of the printed circuit board, and the bridge (500) may form a circuit pattern that is relatively finer than other circuit patterns of the printed circuit board. The bridge (500) may perform a function of electrically connecting electronic components to each other through a bridge circuit (520) composed of a fine circuit pattern, and may perform a function of transmitting an electrical signal from the top and bottom of the printed circuit board.

The bridge insulating layer (510) may include an insulating material, and at this time, the insulating material may be, for example, PID (Photo Image-able Dielectric), but is not limited thereto. For example, a thermosetting resin such as an epoxy resin, a thermoplastic resin such as a polyimide, or a resin in which these resins are mixed with an inorganic filler, or a resin impregnated with an inorganic filler into glass fiber (glass cloth, glass fabric), such as prepreg, ABF (Ajinomoto Build-up Film), FR-4, BT (Bismaleimide Triazine), etc. may be used. When PID is used as a material for the bridge insulating layer (510), the thickness of the bridge insulating layer (510) may be minimized, and a photo via hole may be formed, making it easy to design a bridge circuit (520) at a high density. The insulating material of the bridge insulating layer (510) is not limited to the PID material described above, and even when using other materials, it is desirable to design the bridge insulating layer (510) and the bridge circuit (520) to have a high density.

The bridge circuit (520) is electrically connected to the printed circuit board through the circuit formed on the outermost layer and the bridge pad (530). The bridge circuit (520) may perform various functions depending on the design of the corresponding layer, but includes at least a signal pattern and a signal pad. The bridge circuit (520) may perform the function of connecting different electronic components, but is not limited thereto. The bridge circuit (520) may use a conductive material, specifically a metal material, such as copper (Cu), aluminum (Al), silver (Ag), tin (Sn), gold (Au), nickel (Ni), lead (Pb), titanium (Ti), or alloys thereof. In FIG. 3, the upper outermost layer of the bridge circuit (520) is shown as being buried by the bridge insulating layer (510), but is not limited thereto, and the upper outermost layer of the bridge circuit (520) may have a structure that protrudes more than the bridge insulating layer (510).

Referring to FIG. 4, the conductive connection portion (400) may be disposed between the pad (300) and the bridge pad (530) and function as a means for electrically connecting them.

The conductive connection portion may have a multilayer structure of a first conductive layer (420), a second conductive layer (410), and a third conductive layer (430).

The first conductive layer (420) is disposed between the second conductive layer (410) and the third conductive layer (430). For example, the third conductive layer (430) and the second conductive layer (410) are disposed on the upper surface and the lower surface of the first conductive layer (420), respectively. Based on FIG. 4, the bridge pad (530)—the third conductive layer (430)—the first conductive layer (420)—the second conductive layer (410)—the pad (300) may be disposed in this order from the upper to the lower surface. As described later, when the bridge (500) is laminated on the first insulating layer (112) by thermal curing, a tin (Sn) plating layer may be pressed on the pad (300), so that at least a part of the first conductive layer (420) may be disposed at the interface between the bridge (500) and the first insulating layer (112).

The first conductive layer (420) may include a third metal. The third metal may be a metal different from the first metal and the second metal. The third metal may be copper (Cu), aluminum (Al), silver (Ag), tin (Sn), gold (Au), lead (Pb), titanium (Ti), or alloys thereof, and may preferably be tin (Sn), but is not limited thereto.

The second conductive layer (410) may include the first metal and the third metal. The second conductive layer (410) may be an intermetallic compound layer disposed between the pad (300) and the first conductive layer (420).

The third conductive layer (430) may include the second metal and the third metal. The third conductive layer (430) may be an intermetallic compound layer disposed between the bridge pad (530) and the first conductive layer (420).

As described above, the pad (300) and the bridge pad (530) may include copper (Cu), and the first conductive layer (420) may include tin (Sn), so the second and third conductive layers (410, 430) may include Cu6Sn5 or Cu3Sn4 as an intermetallic compound. As described later, the pad (300) of the printed circuit board according to the present embodiment may be formed by forming a tin (Sn) plating layer without performing surface treatment using nickel (Ni) and palladium (Pd), and then laminating the intermetallic compounds by thermal curing, so that the intermetallic compounds may not include nickel (Ni) and palladium (Pd).

The conductive connection portion (400) of the printed circuit board according to the present embodiment may be formed by using a copper (Cu) and tin (Sn) plating layer. Specifically, a tin (Sn) plating layer may be formed on the copper (Cu) plating layer of the pad (300), and then a bridge (500) may be laminated on the first insulating layer (112) by thermal curing to form intermetallic compounds of copper (Cu) and tin (Sn). Electrical connections may be implemented with intermetallic compounds, and since electrical connections may be implemented under the bridge (500), the degree of freedom in chip and package design may be increased. In addition, since intermetallic compounds may be utilized as heat dissipation paths, heat dissipation characteristics may be improved. In addition, since bridges may be mounted without using a separate soldering process and DAF (Die Attach Film), thinning of the printed circuit board may be promoted. In addition, since intermetallic compounds may be formed in an environment similar to a general insulating layer lamination temperature, the process may be simplified.

The printed circuit board according to the first embodiment may further include an external interconnection layer (620) and an external via layer (630).

The external interconnection layer (620) may be disposed on top (e.g., an outer portion) of the bridge (500) and connected to the bridge circuit layer (520). The external interconnection layer (620) may perform the role of an electrical signal path by mounting electronic components, and may perform the function of connecting the electronic components and the bridge (500).

The external interconnection layer (620) may include a metal material. The metal material may include copper (Cu), aluminum (Al), silver (Ag), tin (Sn), gold (Au), nickel (Ni), lead (Pb), titanium (Ti), and/or alloys thereof, and preferably may include copper (Cu), but is not limited thereto. The external interconnection layer (620) may perform various functions depending on the design. For example, it may include a ground pad, a power pad, a signal pad, etc. In this case, the signal pad may include a pad for electrical connection of various signals, such as data signals, excluding ground and power. The external interconnection layer (620) may be formed by, but is not limited to, one of a Semi Additive Process (SAP), a Modified Semi Additive Process (MSAP), Tenting (TT), or a subtractive method.

The external via layer (630) may penetrate the second insulating layer (113) to electrically connect the external interconnection layer (620) and the bridge circuit layer (520). One side of the external via layer (630) may be connected to the external interconnection layer (620), and the other side may be connected to the bridge circuit layer (520). The external via layer (630) may electrically connect the external interconnection layer (620) and the bridge (500), thereby performing an electrical connection function between electronic components disposed on one side of the external interconnection layer (620).

The external via layer (630) may include a metal material. The metal material may include copper (Cu), aluminum (Al), silver (Ag), tin (Sn), gold (Au), nickel (Ni), lead (Pb), titanium (Ti), or alloys thereof. The external via layer (630) may include a signal via, a ground via, a power via, etc. depending on the design. The external via layer (630) may include a plurality of vias, and each via hole may be completely filled with a metal material, or the metal material may be formed along the wall surface of the via hole. The external via layer (630) may be formed by a plating process, for example, a Semi Additive Process (SAP), a Modified Semi Additive Process (MSAP), a Tenting (TT), etc., and may include a seed layer which is an electroless plating layer and an electrolytic plating layer formed based on the seed layer.

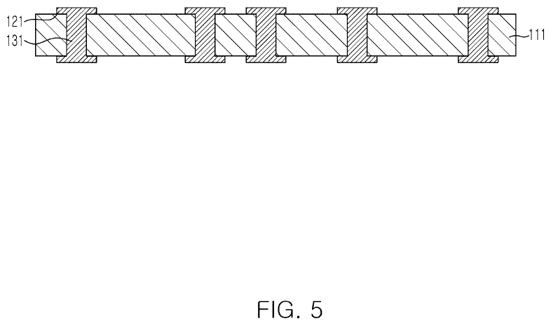

FIGS. 5 to 9 are schematic drawings showing a manufacturing process of a first embodiment of a printed circuit board according to the present disclosure.

Referring to FIG. 5, first, a core layer (111) is prepared. The core layer (111) may be a metal foil laminate plate having metal foil attached to both sides.

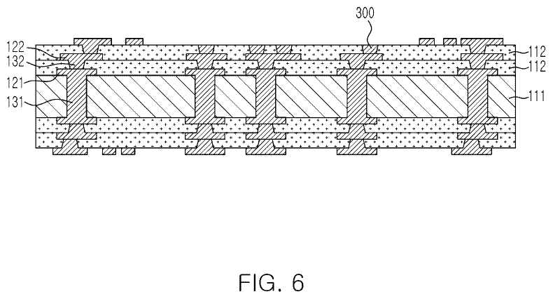

Referring to FIG. 6, a core interconnection layer (121) is formed on both sides of the core layer (111), and a through-via (131) is formed that penetrates the core layer (111) and connects each of the core interconnection layers (121) disposed on both sides of the core layer (111). Next, a first insulating layer (112), a first interconnection layer (122), and a first via layer (132) are formed on both sides of the core layer (111). The first insulating layer (112) may be formed by laminating one or more insulating layers. For example, it may be formed by laminating an uncured prepreg and then curing the same, but the present disclosure is not limited thereto. A pad (300) that is exposed on one side may be formed on the first insulating layer (112) of the uppermost. The core interconnection layer (121), the through-via (131), the first interconnection layer (122), and the first via layer (132) may be formed by forming a via hole using a laser drill, a mechanical drill, etc., and then using a known plating process.

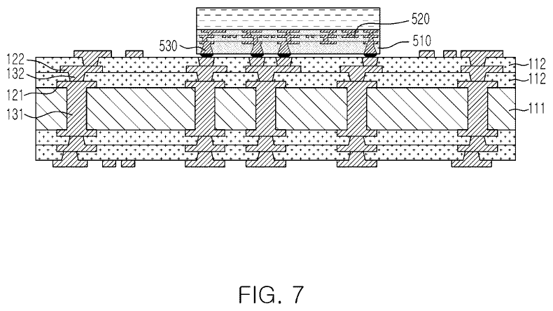

Referring to FIG. 7, a tin (Sn) plating layer is formed on the upper surface of the pad (300). A bridge (500) is disposed on the tin (Sn) plating layer, and the bridge pad (530) and the tin (Sn) plating layer are allowed to come into contact.

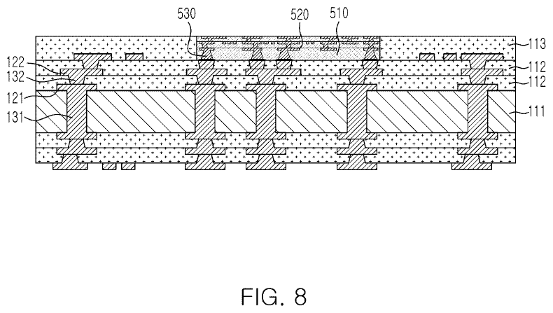

Referring to FIG. 8, a second insulating layer (113) is laminated on the first insulating layer (112). At this time, the bridge (500) is laminated on the first insulating layer (112) by thermal curing, and in this process, a conductive connection portion (400) including intermetallic compounds of copper (Cu) and tin (Sn) may be formed.

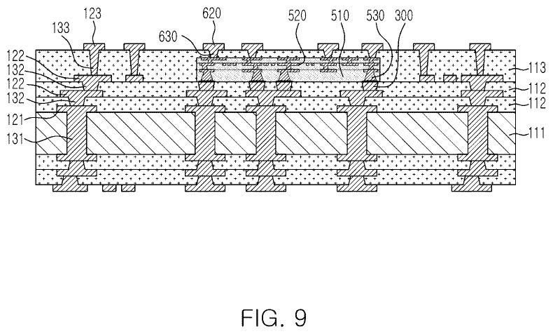

Referring to FIG. 9, a second interconnection layer (123), a second via layer (133), an external interconnection layer (620), and an external via layer (630) may be formed on the upper surface of the second insulating layer (113). The second interconnection layer (123) may be disposed on the second insulating layer (113) and connected to the first interconnection layer (122) through the second via layer (133). The external interconnection layer (620) may be disposed on the upper surface of the bridge (500) and connected to the bridge circuit layer (520) through the external via layer (630). The second interconnection layer (123), the second via layer (133), the external interconnection layer (620), and the external via layer (630) may be formed by a plating process, for example, a Semi Additive Process (SAP), a Modified Semi Additive Process (MSAP), a Tenting (TT), etc., and may include a seed layer, which is an electroless plating layer, and an electrolytic plating layer formed based on the seed layer.

### Second Embodiment

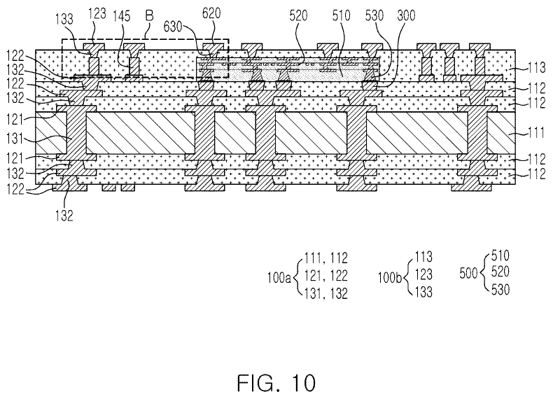

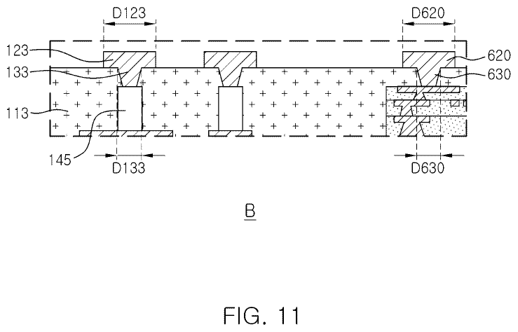

FIG. 10 is a cross-sectional view schematically illustrating a second embodiment of a printed circuit board according to the present disclosure. FIG. 11 is an enlarged view of part B of FIG. 10.

Referring to FIGS. 10 and 11, the printed circuit board according to the second embodiment may further include a metal pillar (145).

The metal pillar (145) may be disposed on the uppermost first interconnection layer (122) among the first interconnection layers, and may be connected to the second via layer (133). For example, the second via layer (133) may be connected to the first interconnection layer (122) by penetrating at least a portion of the second insulating layer (113). When considering the top view of the printed circuit board, the metal pillar (145) may be formed in an outer area of the printed circuit board where the bridge (500) is not disposed. The metal pillar (145) may be positioned at the same level as the upper surface of the bridge (500). The metal pillar (145) may secure a specific height in the printed circuit board area where the bridge (500) is not disposed, thereby facilitating the formation of the second interconnection layer (123) and the second via layer (133). The second via layer (133) and the external via layer (630) may be formed in the same process, and when heterogeneous vias are formed by a plating process, it may be difficult to secure fairness. Therefore, the metal pillar (145) may be formed first, and via layers (133, 630) having the same height and diameter may be formed by the same process, thereby securing fairness. Accordingly, the upper pads (123, 620) may also be formed by the same process, thereby securing fairness, and a process for improving the precision of the pad pitch may not be necessary.

The metal pillar (145) may include a metal material. The metal material may include copper (Cu), aluminum (Al), silver (Ag), tin (Sn), gold (Au), nickel (Ni), lead (Pb), titanium (Ti), and/or alloys thereof, and may preferably include copper (Cu), but is not limited thereto. The metal pillar (145) may be formed by any one of SAP (Semi Additive Process), MSAP (Modified Semi Additive Process), TT (Tenting), or a subtractive method, but is not limited thereto.

The metal pillar (145) may have a pillar shape with a non-slanted side surface and a constant width.

Referring to FIG. 11, the diameter (D123) of at least one of the second interconnection layers (123) may be substantially the same as the diameter (D620) of at least one of the external interconnection layers (620). The diameters may be measured by an optical microscope or scanning electron microscope. Other methods and/or tools appreciated by one of ordinary skill in the art, even if not described in the present disclosure, may also be used.

The diameter (D133) of the second via layer (133) may be substantially the same as the diameter (D630) of the external via layer (630). As shown in FIG. 11, when the side surface of the via (133, 630) is tapered, the diameter of one end of the via may be larger than the diameter of the other end. In this case, as shown in FIG. 11, the relatively large diameter of one end may be measured and used as the diameter. However, it is not necessarily limited thereto, and the diameter of the other end may be measured according to convenience. The diameter of the via may be measured multiple times, and the arithmetic mean of the values measured multiple times may be used as the diameter.

The height of the second via layer (133) may be substantially the same as the height of the external via layer (630).

As used herein, the meaning of “substantially the same” includes not only things that are numerically exactly the same, but also things that are designed to be the same size, but may be considered identical by a person skilled in the art even if there are slight differences within the tolerance range due to manufacturing process tolerance or material characteristics. The tolerance may be ±1%, ±5%, or ±10%, and other suitable tolerances. As used herein, the expression “substantially the same” also allows for approximations, inaccuracies and limits of measurement under the relevant circumstances.

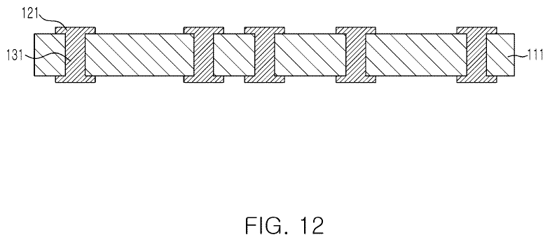

FIGS. 12 to 16 are schematic drawings showing a manufacturing process of a second embodiment of a printed circuit board according to the present disclosure.

Referring to FIG. 12, first, a core layer (111) is prepared. The core layer (111) may be a metal foil laminated plate having metal foil attached to both sides.

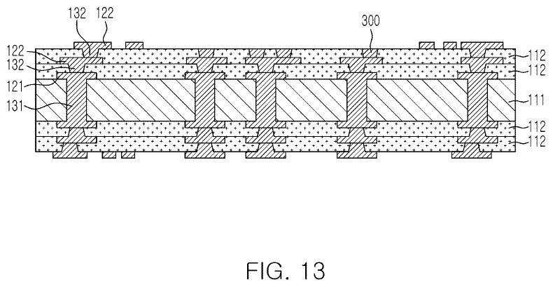

Referring to FIG. 13, a core interconnection layer (121) is formed on both sides of the core layer (111), and a through-via (131) is formed that penetrates the core layer (111) and connects each of the core interconnection layers (121) disposed on both sides of the core layer (111). Next, a first insulating layer (112), a first interconnection layer (122), and a first via layer (132) are formed on both sides of the core layer (111). The first insulating layer (112) may be formed by laminating one or more insulating layers. For example, it may be formed by laminating an uncured prepreg and then curing it, but it is not limited thereto. A pad (300) that is exposed on one side may be formed on the uppermost first insulating layer (112). The core interconnection layer (121), through-via (131), the first interconnection layer (122), and the first via layer (132) may be formed by forming a via hole using a laser drill, a mechanical drill, etc., and then using a known plating process.

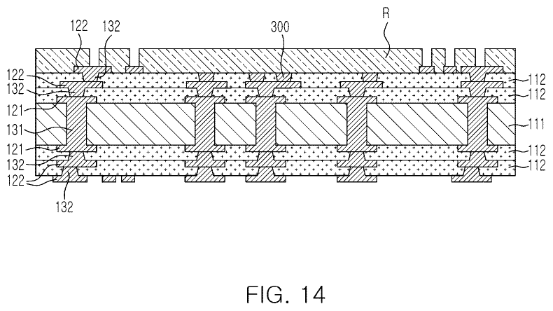

Referring to FIG. 14, a photoresist (R) is formed on the first insulating layer (112). At this time, an opening may be formed in the area where a metal pillar (145) is formed in the photoresist (R) through an exposure and development process.

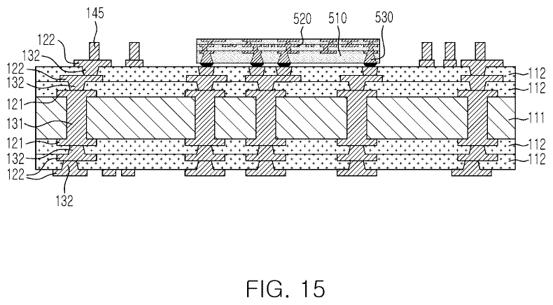

Referring to FIG. 15, a metal pillar (145) may be formed using a photoresist (R) through a process such as plating, and then the photoresist (R) may be removed through a process such as peeling. Next, a tin (Sn) plating layer is formed on the upper surface of the pad (300). A bridge (500) is disposed on the tin (Sn) plating layer, and the bridge pad (530) and the tin (Sn) plating layer are made to come into contact.

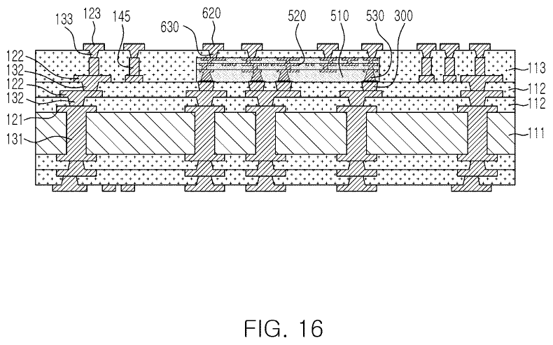

Referring to FIG. 16, a second insulating layer (113) is laminated on the first insulating layer (112). At this time, the bridge (500) is laminated on the first insulating layer (112) by thermal curing, and in this process, a conductive connection portion (400) including intermetallic compounds of copper (Cu) and tin (Sn) may be formed. Thereafter, a second interconnection layer (123), a second via layer (133), an external interconnection layer (620), and an external via layer (630) may be formed on the upper surface of the second insulating layer (113).

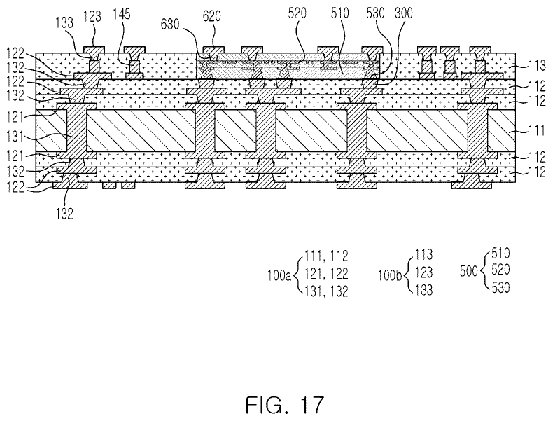

FIG. 17 is a drawing showing a modified example of a second embodiment of a printed circuit board according to the present disclosure.

Referring to FIG. 17, a printed circuit board according to a modified example may have a bridge (500) exposed from the upper surface of the second substrate portion. For example, the second insulating layer (113) may not cover the upper surface of the bridge (500), and the upper surface of the second insulating layer (113) may be positioned at the same level as the upper surface of the bridge (500).

The metal pillar (145) may have an upper surface positioned at a level lower than the upper surface of the bridge (500). An external interconnection layer (620) may be disposed on the upper surface of the bridge (500), and an external via layer (630) may partially penetrate the bridge (500) and be connected to the bridge circuit layer (520).

### Third Embodiment

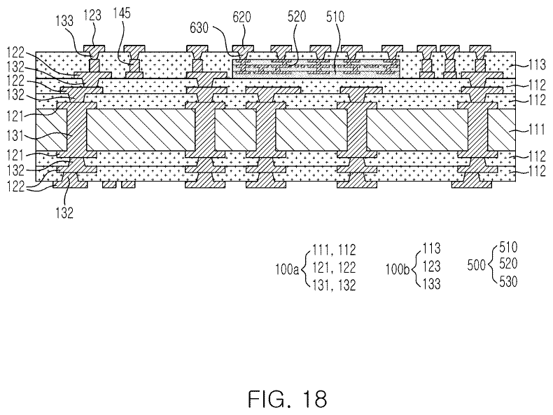

FIG. 18 is a cross-sectional view schematically illustrating a third embodiment of a printed circuit board according to the present disclosure.

Referring to FIG. 18, the printed circuit board according to the third embodiment may omit the pad (300), the conductive connection portion (400), and the bridge pad (530) extending to the bridge lower surface. For example, the bridge (500) may not be electrically connected to the printed circuit board through one side (the lower surface). However, it is not excluded that the bridge (500) may be electrically connected to the printed circuit board through the upper surface and the side surface.

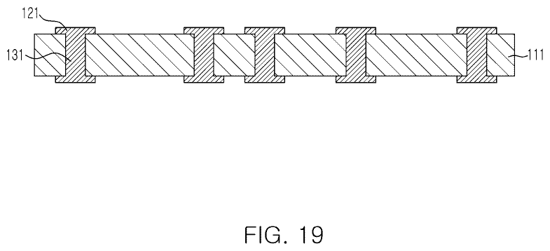

FIG. 19 to FIG. 24 are drawings schematically illustrating a manufacturing process of the third embodiment of a printed circuit board according to the present disclosure.

Referring to FIG. 19, first, a core layer (111) is prepared. The core layer (111) may be a metal foil laminate having metal foil attached to both sides.

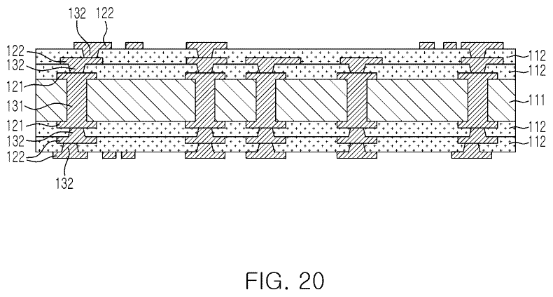

Referring to FIG. 20, a core interconnection layer (121) is formed on both sides of the core layer (111), and a through-via (131) is formed to connect each of the core interconnection layers (121) disposed on both sides of the core layer (111) by penetrating the core layer (111). Next, a first insulating layer (112), a first interconnection layer (122), and a first via layer (132) are formed on both sides of the core layer (111).

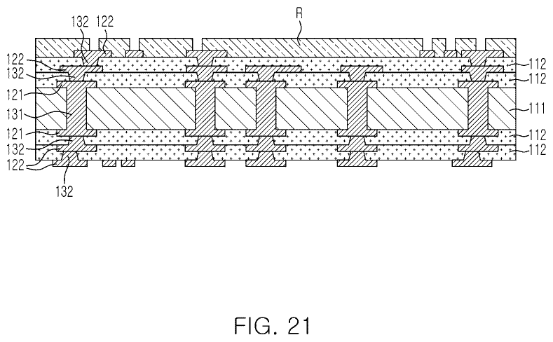

Referring to FIG. 21, a photoresist (R) is formed on the first insulating layer (112). At this time, an opening may be formed in the photoresist (R) in an area where a metal pillar (145) is formed through an exposure and development process.

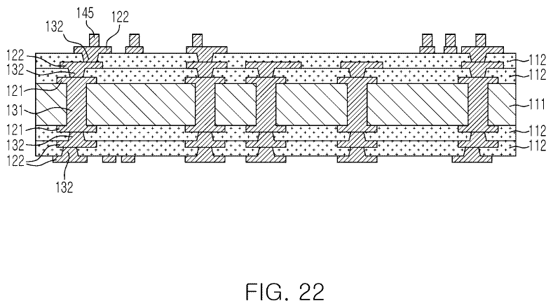

Referring to FIG. 22, a metal pillar (145) is formed by a process such as plating using the photoresist (R), and then the photoresist (R) may be removed by a process such as peeling.

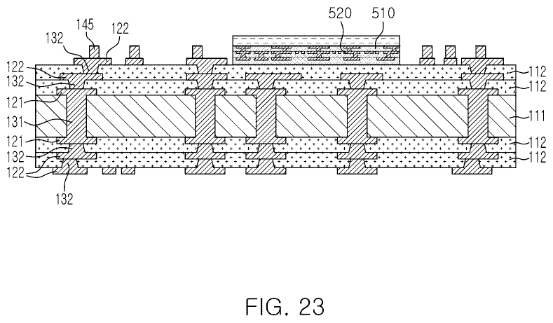

Referring to FIG. 23, a bridge (500) may be disposed on the first insulating layer (112). According to the present embodiment, since the conductive connection portion (400) is not formed, an electrical connection with the substrate may not be formed through the lower portion of the bridge (500).

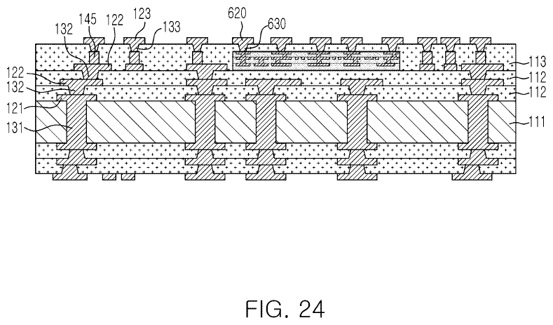

Referring to FIG. 24, a second insulating layer (113) is laminated on the first insulating layer (112). Thereafter, a second interconnection layer (123), a second via layer (133), an external interconnection layer (620), and an external via layer (630) may be formed on the upper surface of the second insulating layer (113).

As set forth above, according to an embodiment, a printed circuit board having a bridge embedded therein, including a high-density circuit layer and a method of manufacturing the same may be provided.

In this disclosure, the term “connected” includes not only direct connection but also indirect connection. In addition, the term “electrically connected” includes both cases where the two are physically connected and cases where the two are not connected.

In this disclosure, the expressions “first”, “second,” etc. are used to distinguish one component from another component, and do not limit the order and/or importance of the components. In some cases, without exceeding the scope of the rights, the first component may be named the second component, and similarly, the second component may be named the first component.

The expression “example” used in this disclosure does not mean an identical embodiment, and is provided to emphasize and explain each unique feature. However, the examples presented above do not exclude implementation in combination with features of other examples. For example, even if a matter described in a specific example is not described in another example, it may be understood as a description related to the other example, unless there is a description that is contrary or contradictory to that matter in the other example.

The terms used in this disclosure are used for the purpose of describing examples only and are not intended to limit this disclosure. In this case, singular expressions include plural expressions unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a first substrate portion including a pad including a first metal, the pad being disposed in a first portion of the first substrate portion;
a second substrate portion disposed on the first substrate portion;
a bridge at least partially disposed within the second substrate portion, and including a bridge pad including a second metal, the bridge pad being disposed in a first portion of the bridge; and
a conductive connection portion disposed between the pad and the bridge pad,
wherein the conductive connection portion includes a first conductive layer including a third metal, a second conductive layer including the first metal and the third metal, and a third conductive layer including the second metal and the third metal, and
wherein the first conductive layer is disposed between the second conductive layer and the third conductive layer.

2. The printed circuit board of claim 1, wherein the first metal and the second metal are the same metal, and the third metal includes a metal different from the first metal and the second metal.

3. The printed circuit board of claim 1, wherein the first metal and the second metal include copper (Cu), and the third metal includes tin (Sn).

4. The printed circuit board of claim 1, wherein the second conductive layer includes an intermetallic compound, and the second conductive layer is disposed between the first conductive layer and the pad.

5. The printed circuit board of claim 1, wherein the third conductive layer includes an intermetallic compound, and the third conductive layer is disposed between the first conductive layer and the bridge pad.

6. The printed circuit board of claim 1, wherein the first substrate portion includes one or more first insulating layers, one or more first interconnection layers disposed on or within the one or more first insulating layers, and one or more first via layers penetrating at least one of the one or more first insulating layers.

7. The printed circuit board of claim 6, wherein the one or more first insulating layers include two or more first insulating layers,
a first surface of the bridge is in direct contact with an outer first insulating layer among the two or more first insulating layers.

8. The printed circuit board of claim 6, wherein the second substrate portion includes a second insulating layer covering at least a portion of a side surface of the bridge, a second interconnection layer disposed on the second insulating layer, and a second via layer penetrating at least a portion of the second insulating layer.

9. The printed circuit board of claim 8, further comprising an external interconnection layer disposed on an outermost portion of the bridge and connected to the bridge,
wherein at least one of the second interconnection layers has a diameter substantially the same as that of at least one of the external interconnection layers.

10. The printed circuit board of claim 8, wherein the second insulating layer covers a second surface of the bridge.

11. The printed circuit board of claim 8, wherein the one or more interconnection layers include two or more interconnection layers, and
the printed circuit board further comprising a metal pillar disposed on an outer first interconnection layer among the two or more first interconnection layers, and
the metal pillar is connected to the second via layer.

12. The printed circuit board of claim 11, wherein a first surface of the metal pillar is located at the same level as a second surface of the bridge.

13. The printed circuit board of claim 8, wherein a first surface of the second insulating layer is located at the same level as a second surface of the bridge.

14. The printed circuit board of claim 1, wherein the bridge is exposed from a first surface of the second substrate portion.

15. The printed circuit board of claim 1, wherein the first metal and the second metal are the same metal, and the third metal is a metal different from the first metal and the second metal.

16. The printed circuit board of claim 1, wherein the first metal and the second metal are copper (Cu), and the third metal is tin (Sn).

17. The printed circuit board of claim 7, wherein the outer first insulating layer is disposed in the first portion of the first substrate portion.

18. The printed circuit board of claim 11, wherein the outer first interconnection layer is disposed in the first portion of the first substrate portion.

19. The printed circuit board of claim 11, wherein the metal pillar is disposed outside the bridge, the bridge pad has substantially the same diameter as the pad, and the pad is disposed outside the bridge.
